(19) United States
(12) Patent Application Publication
(10) Pub. No.: US 2026/0255903 A1
(43) Pub. Date: Aug. 27, 2026

(54) CHIP MANUFACTURING METHOD, CHIP DISTANCE INCREASING METHOD, AND PROCESSING APPARATUS

(71) Applicant: DISCO CORPORATION, Tokyo (JP)

(72) Inventors: Chisato YAMADA, Tokyo (JP); Yuhei FUJII, Tokyo (JP)

(21) Appl. No.: 19/545,465

(22) Filed: Feb. 20, 2026

(30) Foreign Application Priority Data
Feb. 27, 2025 (JP) 2025-029810
Jan. 20, 2026 (JP) 2026-007264

(51) Int. Cl. H10P 58/00; H10P 72/70

(52) U.S. Cl. CPC H10P 58/00; H10P 72/7402; H10P 72/7416; H10P 72/7442

(57) ABSTRACT

Provided is a chip manufacturing method that divides a workpiece to manufacture chips. The chip manufacturing method includes dividing the workpiece into a plurality of chips by expanding a sheet to which the workpiece in which division initiating points are formed is fixed, after the workpiece has been divided into a plurality of chips, forming, in a part of the expanded sheet, a protruding portion protruding relative to a surface formed by other portions, and welding portions of the sheet that are in contact with each other in the protruding portion, by heating the protruding portion.

### BACKGROUND OF THE INVENTION

### Field of the Invention

The present invention relates to a method of manufacturing chips by dividing a workpiece, a method for increasing a distance between chips manufactured by dividing a workpiece, and a processing apparatus that performs such processes.

### Description of the Related Art

Chips (device chips) including devices such as electronic circuits are indispensable components in electronic appliances, typically, mobile phones and personal computers. Device chips are, for example, fabricated by demarcating a wafer made of such a material as silicon and sapphire into a plurality of areas by projected dicing lines (streets), forming devices respectively in the areas, and dividing the wafer along the projected dicing lines.

In dividing a plate-shaped workpiece as exemplified by a wafer into a plurality of chips, for example, a method of focusing a laser beam of a wavelength transmittable through the workpiece on the projected dicing lines and modifying the portion is used. The portion modified by the laser beam is fragile compared to other portions, so that, when external force is applied to the workpiece, the workpiece is divided into a plurality of chips along the projected dicing lines.

When a workpiece is to be divided by such a method, a sheet having a property of extending when force is applied thereto is typically fixed to the workpiece. For example, when a sheet affixed to one surface of a plate-shaped workpiece is expanded along a surface direction, force is applied to the workpiece via the sheet, and the workpiece is divided. Moreover, when the sheet is further expanded, the gaps between the adjacent chips are enlarged, making it easier to perform such work as pickup of the chips.

On an outer edge portion of the sheet, an annular frame is fixed for convenience at the time of transportation, for example. That is, the workpiece is handled in the form of a frame unit in which the workpiece is affixed to a central portion of a circular sheet and a frame is affixed to the outer edge portion.

The sheet forming a part of the frame unit is expanded by an expander being pressed against the sheet in a direction perpendicular to the surface, for example, in a state in which the outer edge portion is firmly fixed to the frame.

Here, at the time when the sheet is expanded, the frame would not expand together with the sheet, so that the expanded sheet may slacken on the inner side of the annular frame.

In a state in which the sheet is slackened, the sheet may sway during transportation and the like, and the adjacent chips may collide with each other and break in some cases. Moreover, the expanded portion of the sheet may shrink as time passes, and the gaps between the adjacent chips may narrow in some cases. A smaller distance between chips causes difficulty in picking up individual chips.

In view of this, for example, a technique of applying heat to a portion of the expanded sheet between the workpiece and the frame and proactively shrinking this portion has been proposed as described in Japanese Patent Laid-open No. 2005-142365. In the technique described in Japanese Patent Laid-open No. 2005-142365, an area of the sheet (dicing tape) that surrounds the workpiece is shrunk, so that the sheet is stretched, preventing adjacent chips from colliding with each other. Moreover, this makes it less likely for the sheet to shrink at portions corresponding to the gaps between the adjacent chips, so that the gaps between the chips are maintained.

### SUMMARY OF THE INVENTION

However, how easily a sheet shrinks by heat differs depending on the material, size, thickness and the like of the sheet. When a sheet that is less likely to shrink by heat is used, the problems caused by the slack of the sheet would not be solved by the method described above. Moreover, even when a sheet that is likely to shrink by heat is used, if the chips are small in size or the distance between the adjacent chips is intended to be even more increased, the abovementioned method could not sufficiently solve the problems.

Accordingly, an object of the present invention is to provide a new chip manufacturing method, chip distance increasing method, and processing apparatus that are capable of solving the problems caused by the slack in a sheet.

In accordance with an aspect of the present invention, there is provided a chip manufacturing method that divides a workpiece to manufacture chips, the manufacturing method including dividing the workpiece into a plurality of chips by expanding a sheet to which the workpiece in which division initiating points are formed is fixed, after the workpiece has been divided into a plurality of chips, forming, in a part of the sheet that has been expanded, a protruding portion protruding relative to a surface formed by other portions, and welding a plurality of portions of the sheet that form the protruding portion and are in contact with each other, by heating the protruding portion.

According to the aspect of the present invention, preferably, when the sheet is to be welded, while the protruding portion is heated from one of surfaces forming an outer side of the protruding portion, another one of the surfaces forming the outer side of the protruding portion is supported by a support member.

According to the aspect of the present invention, preferably, the sheet is welded in a state in which a cover member is arranged between a heat source used for welding and the workpiece, and the cover member includes the support member that supports the protruding portion.

According to the aspect of the present invention, preferably, the chip manufacturing method further includes, after the workpiece is divided but before the protruding portion is formed, holding a surface of the sheet opposite a surface to which the workpiece is fixed, by a holding surface of the workpiece holding unit including a member having the holding surface for holding the workpiece, the cover member is disposed on the workpiece before the protruding portion is formed, and the protruding portion is formed in a state in which the sheet is sandwiched between the holding surface of the workpiece holding unit and the cover member.

According to the aspect of the present invention, when the protruding portion is to be formed, an area around an area sandwiched between the holding surface of the workpiece holding unit and the cover member in the sheet is further expanded, in a state in which a part of the sheet is sandwiched between the holding surface of the workpiece holding unit and the cover member.

According to the aspect of the present invention, preferably, when the sheet is to be welded, the protruding portion is heated by supply of warm air that flows toward the protruding portion from a side opposite the side where the support member is present across the protruding portion.

According to the aspect of the present invention, preferably, when the protruding portion is to be formed, the protruding portion is formed by the slackened sheet drooping downward.

In accordance with another aspect of the present invention, there is provided a chip distance increasing method of increasing a distance between a plurality of chips fixed to a sheet, the method including increasing the distance between the plurality of chips by expanding the sheet to which the plurality of chips are fixed, after a workpiece has been divided into a plurality of chips, forming, in a part of the expanded sheet, a protruding portion protruding relative to a surface formed by other portions, and welding portions of the sheet that form the protruding portion, by heating the protruding portion.

In accordance with a further aspect of the present invention, there is provided a processing apparatus that processes a sheet to which a workpiece is fixed, the processing apparatus including a sheet holding unit that holds the sheet to which the workpiece is fixed, a sheet expanding unit that expands the sheet held on the sheet holding unit, and a welding unit that heats a protruding portion formed in a part of the sheet expanded by the sheet expanding unit, as a portion protruding relative to other portions, and welds a plurality of portions of the sheet that form the protruding portion and are in contact with each other.

In the chip manufacturing method, the chip distance increasing method, and the processing apparatus according to the aspects of the present invention, after the chips have been manufactured by the workpiece being divided through expansion of the sheet to which the workpiece is fixed, and the distance between the chips has been increased, the protruding portion formed in a part of the sheet can be welded. This suppresses slack from being generated in the sheet and such events as contact between chips from occurring.

As described above, the chip manufacturing method, the chip distance increasing method, and the processing apparatus according to the aspects of the present invention provide a new chip manufacturing method, chip distance increasing method, and processing apparatus that are capable of solving the problems caused by the slack in the sheet.

The above and other objects, features and advantages of the present invention and the manner of realizing them will become more apparent, and the invention itself will best be understood from a study of the following description and appended claims with reference to the attached drawings showing a preferred embodiment of the present invention.

### BRIEF DESCRIPTION OF THE DRAWINGS

FIG. 1 is an exploded perspective view schematically illustrating an example of a configuration of a workpiece unit;

FIG. 2 is an exploded perspective view illustrating an example of a configuration of main parts of a processing apparatus;

FIG. 3 is a perspective view illustrating an example of a state in which the workpiece unit is held on the processing apparatus;

FIG. 4 is a flowchart illustrating an example of procedures related to a chip manufacturing method and a chip distance increasing method;

FIG. 5 is a cross-sectional side view schematically illustrating a state of each part in one step of the procedures illustrated in FIG. 4 and a diagram illustrating an example of layout of each part in a sheet arranging step;

FIG. 6 is a cross-sectional side view schematically illustrating a state of each part in another step of the procedures illustrated in FIG. 4 and a diagram illustrating an example of layout of each part in a sheet expanding step;

FIG. 7 is a cross-sectional side view schematically illustrating a state of each part in still another step of the procedures illustrated in FIG. 4 and a diagram illustrating an example of layout of each part in a workpiece holding step;

FIG. 8 is a cross-sectional side view schematically illustrating a state of each part in yet another step of the procedures illustrated in FIG. 4 and a diagram illustrating an example of layout of each part in a protecting step;

FIG. 9 is a cross-sectional side view schematically illustrating a state of each part in a still further step of the procedures illustrated in FIG. 4 and a diagram illustrating an example of layout of each part in a protruding portion forming step;

FIG. 10 is a cross-sectional side view schematically illustrating a state of each part in a still further step of the procedures illustrated in FIG. 4 and a diagram illustrating an example of a state of each part in a welding step;

FIG. 11 is a cross-sectional side view schematically illustrating a state of each part in a still further step of the procedures illustrated in FIG. 4 and a diagram illustrating another example of a state of each part in the welding step;

FIG. 12 is a cross-sectional side view schematically illustrating another example of a state of each part in the welding step;

FIG. 13 is a cross-sectional side view schematically illustrating still another example of a state of each part in the welding step;

FIG. 14 is a cross-sectional side view schematically illustrating yet another example of a state of each part in the welding step; and

FIG. 15 is a cross-sectional side view schematically illustrating a still further example of a state of each part in the welding step.

### DETAILED DESCRIPTION OF THE PREFERRED EMBODIMENT

An embodiment of the present invention will be described in detail below with reference to the accompanying drawings.

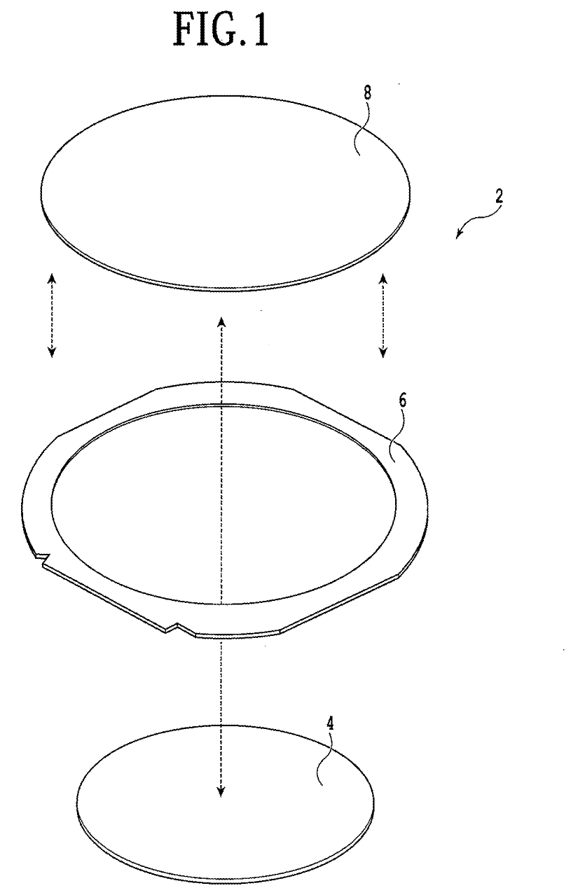

First, a workpiece unit to be handled in the present embodiment is described. FIG. 1 is an exploded perspective view schematically illustrating an example of a configuration of a workpiece unit. The workpiece unit denoted by 2 is formed by a workpiece 4, a frame 6, and a sheet 8 as components.

The workpiece 4 is, for example, a disk-shaped wafer formed of a semiconductor material such as single crystal silicon. The plate-shaped workpiece 4 has a plurality of projected dicing lines (streets) set thereon in a grid pattern and is demarcated by the streets into a plurality of rectangular areas. A device exemplified by an integrated circuit (IC), a large scale integration (LSI) circuit, a light emitting diode (LED), and a micro-electromechanical systems (MEMS) device is formed on a surface of each of the areas demarcated by the streets.

The workpiece 4 is subjected to a modifying process using laser processing along the streets, and the portion of the workpiece 4 subjected to the modifying process functions as an area serving as a division initiating point that is used when the workpiece 4 is to be divided. Note that the method of forming a dividing portion in the workpiece 4 is not limited to laser processing. For example, it is also possible to assume such a process that a groove is formed on a face side of the workpiece 4 by cutting the face side with a blade and is used as the dividing portion.

The workpiece 4 is not limited to any particular types, materials, shapes, structures, and sizes, for example. For example, the workpiece 4 may be a substrate (wafer) formed of a material such as a semiconductor (GaAs, InP, GaN, SiC, or the like) other than silicon, sapphire, glass, ceramics, resin, or metal. Moreover, the devices formed in the workpiece 4 are not limited to any particular types, numbers, shapes, structures, sizes, and layouts, for example.

The workpiece 4 is handled in a state of a frame unit in which the workpiece 4 is held on the annular frame 6 illustrated in FIG. 1, for the purpose of facilitating such handling as transportation and holding of the workpiece 4. The frame 6 is a plate-shaped component formed of metal such as stainless steel (SUS), for example. An opening that penetrates the frame 6 in a thickness direction is provided in a central portion of the frame 6. The diameter of the opening is set to be larger than the diameter of the workpiece 4.

The workpiece 4 is supported by the frame 6 via the sheet 8. The sheet 8 is, for example, constituted by a circular film-shaped base material having a larger diameter than the central opening of the frame 6 and an adhesive layer provided on the base material. The base material includes, for example, elastic resin such as polyolefin, polyvinyl chloride, or polyethylene terephthalate. The adhesive layer is formed of a material such as an epoxy-based, acryl-based, or rubber-based adhesive, for example. This material is applied to at least one surface of the base material to form the adhesive layer.

In a state in which the workpiece 4 is disposed inside the opening of the frame 6 and surrounded by the frame 6, a central portion of the sheet 8 is affixed to the workpiece 4, and an outer peripheral portion of the sheet 8 is affixed to the frame 6. The workpiece 4 is thus supported by the frame 6. In this state, between the outer peripheral portion of the sheet 8 affixed and fixed to the frame 6 and a central area of the sheet 8 affixed and fixed to the workpiece 4, an adhesive surface of the sheet 8 that is affixed to neither the frame 6 nor the workpiece 4 is exposed in a ring pattern.

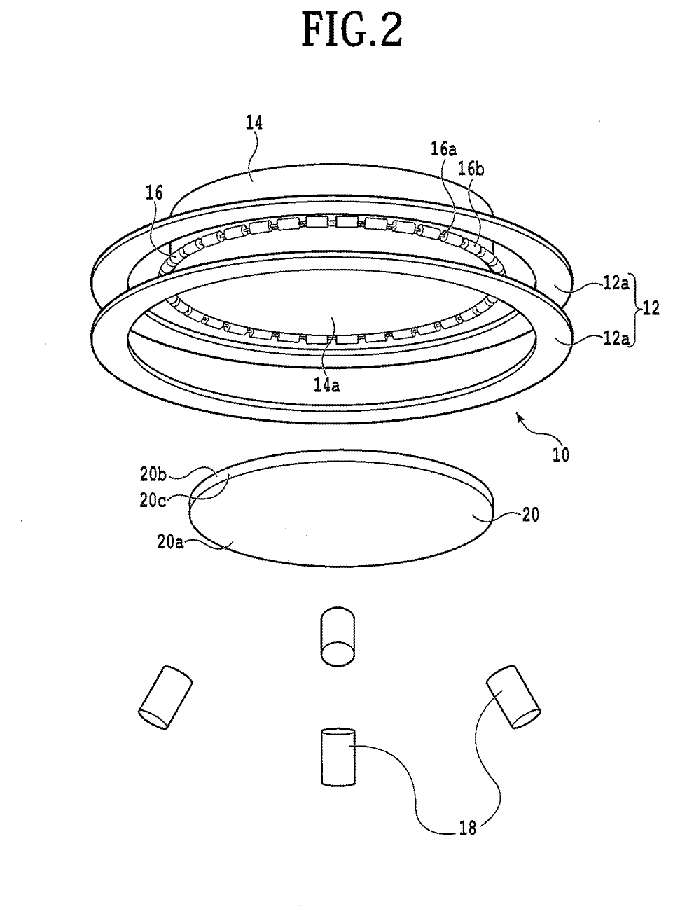

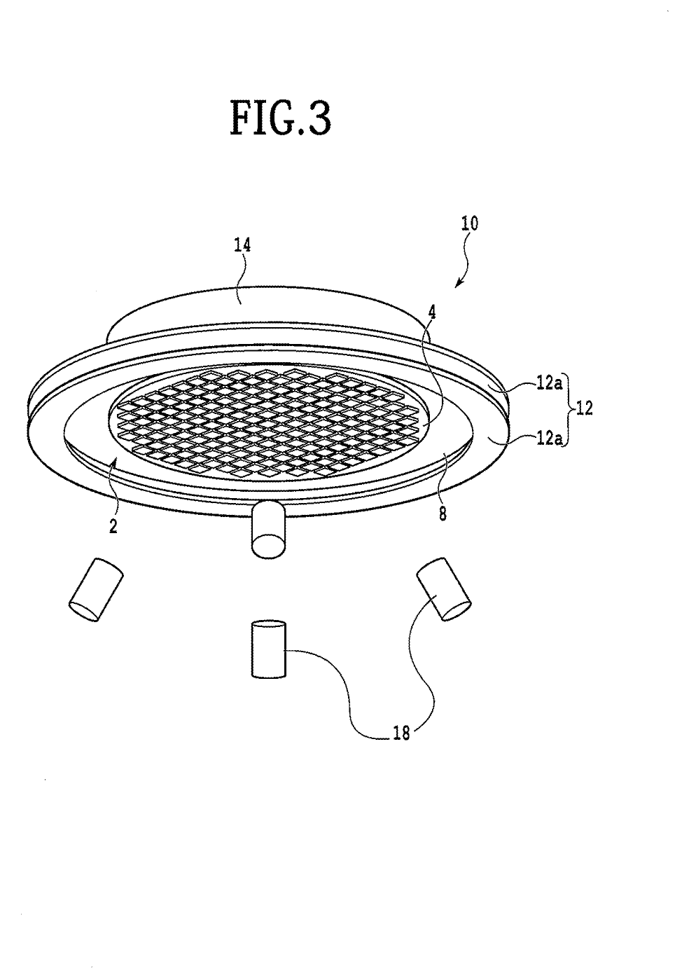

FIG. 2 is an exploded perspective view illustrating an example of a configuration of main parts of a processing apparatus 10 that handles the workpiece unit 2 described above. FIG. 3 is a perspective view illustrating an example of a state in which the workpiece unit 2 is held on the processing apparatus 10.

The processing apparatus 10 according to the present embodiment includes a sheet holding unit 12, a workpiece holding unit 14, a sheet expanding unit 16, and a welding unit 18.

The sheet holding unit 12 is a unit that holds the sheet 8 which is part of the workpiece unit 2 illustrated in FIG. 1 and to which the workpiece 4 is fixed. In the example illustrated in FIGS. 2 and 3, the sheet holding unit 12 includes two annular members (sandwiching members 12a) each having an inner peripheral portion greater in diameter (size in the direction crossing the thickness direction) than the outer peripheral portion of the workpiece 4. The two annular members forming the sandwiching members 12a are each a plate-shaped member formed with a material such as metal and resin, for example.

The two sandwiching members 12a sandwich from both sides an area of the sheet 8 that is on an outer side of the outer periphery of the workpiece 4 and hold the area in such a manner as to surround the workpiece 4 as illustrated in FIG. 3. In holding the sheet 8, the two sandwiching members 12a may sandwich and hold the sheet 8 from both surfaces or hold the sheet 8 by sandwiching and holding from both surfaces the frame 6 fixed to the sheet 8.

When the two sandwiching members 12a are to sandwich and hold the sheet 8, the diameter of the inner peripheral portion of each of the sandwiching members 12a is set to be smaller than the diameter of the outer peripheral portion of the sheet 8. When the two sandwiching members 12a are to sandwich and hold the frame 6 fixed to the sheet 8, the diameter of the inner peripheral portion of each of the sandwiching members 12a is set to be smaller than the diameter of the outer peripheral portion of the frame 6.

When the sheet 8 or the frame 6 is to be sandwiched by the two sandwiching members 12a, for example, force is applied from both sides to the two sandwiching members 12a sandwiching the sheet 8 or the frame 6, by a clip (not illustrated) that sandwiches an object by elastic force. Note that other units may be adopted as the unit for applying force to the sandwiching member 12a, such as a mechanism using magnetic force, for example.

Moreover, though omitted from illustration, the sheet holding unit 12 may include one sandwiching member, for example, and be configured to hold the sheet 8 by sandwiching the sheet 8 between the one sandwiching member and the frame 6. In that case, the diameter of the inner peripheral portion of the sandwiching member is set to be smaller than the diameter of the outer peripheral portion of the sheet 8.

While the sandwiching member 12a is illustrated as an annular member here, the sandwiching member 12a is not limited to having an annular shape and may have other shapes that can hold the sheet 8 in a suitable manner. For example, the sandwiching member 12a may have a C-shape or be in a form in which a plurality of members are disposed in a circumferential direction in such a manner as to surround the workpiece 4.

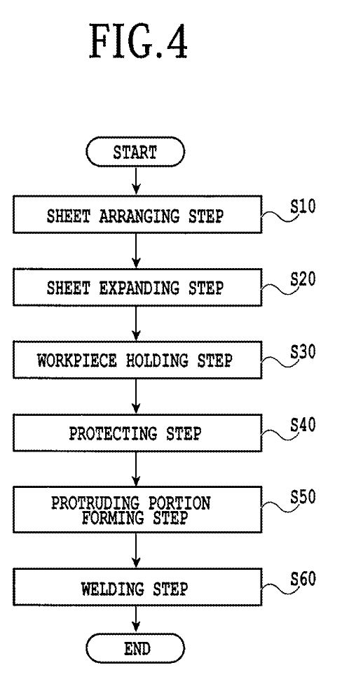

Yet, in order to have the sheet 8 uniformly expanded in the procedures described below (sheet expanding step S20; see FIG. 4), an annular shape surrounding the workpiece 4 by forming a line closing the periphery of the workpiece 4 can be said to be suitable as the shape of the sandwiching member 12a. This is because an annular shape makes it easier to apply uniform force to the sheet 8 along the surface direction.

The workpiece holding unit 14 is a unit for holding the workpiece 4 and is, for example, a chuck table that holds the workpiece 4 by a negative pressure. The workpiece holding unit 14, which is a chuck table, includes a frame made of a material such as ceramics or metal, for example, and a suction member attached to the frame. The frame is of a substantially cylindrical shape as a whole and has a circular recess defined in an end face thereof.

The suction member is a disk-shaped member made of porous ceramics or metal, for example. If the suction member is made of metal or the like, the suction member has a hole that penetrates the suction member in the thickness direction.

The disk-shaped suction member is fitted in the recess defined in the frame. A fluid channel through which gas flows is defined in the frame, and an unillustrated suction source such as a vacuum pump is connected to the fluid channel. When a negative pressure is supplied to the fluid channel by the suction source being actuated, an object such as the workpiece 4 in contact with a face side of the suction member is held under suction on the face side through the holes of the suction member.

In this way, the end face of the workpiece holding unit 14 in which the suction member is provided forms a holding surface 14a that holds under suction the workpiece 4, for example. The holding surface 14a of the workpiece holding unit 14 can hold under suction the workpiece 4 with the sheet 8 sandwiched therebetween, for example, or hold under suction the workpiece 4 in direct contact with the workpiece 4.

In the example illustrated here, the workpiece holding unit 14 is attached to the processing apparatus 10 in a state in which the holding surface 14a is facing downward, and the workpiece 4 is held under suction on the holding surface 14a that is located on the upper side, by the abovementioned suction force.

Note that the direction in which the holding surface 14a is facing in the workpiece holding unit 14, the mechanism of holding under suction the workpiece 4, the shape and material of each part, and the like are not limited to the examples illustrated here. The workpiece holding unit 14 may be a unit having any form or mechanism that can suitably hold an assumed object (workpiece 4). For example, the holding surface 14a may face upward or laterally, and the workpiece holding unit 14 may hold the workpiece 4 by a mechanism other than holding the workpiece 4 under suction by a negative pressure.

Alternatively, the workpiece holding unit 14 may not have a mechanism for holding the object by suction force or the like, and may be a member that holds the workpiece 4 by sandwiching the workpiece 4 between the member and a cover member 20 described later, for example.

The member that is part of the workpiece holding unit 14 and has a holding surface may, for example, have a plate shape such as a disk shape or a polygonal shape or a cylindrical shape, a prismatic shape, a truncated cylinder shape, or a truncated prism shape. The workpiece holding unit 14 may have any shape insofar as the workpiece holding unit 14 has a holding surface capable of holding the workpiece 4.

The sheet expanding unit 16 is a unit for expanding the sheet 8 held on the sheet holding unit 12 and is formed as a ring-shaped member in the present embodiment as illustrated in FIG. 2.

In the procedures described below (sheet expanding step S20), the sheet expanding unit 16 expands the sheet 8 by coming into contact with the sheet 8 held on the sheet holding unit 12 and applying force to the sheet 8. Hence, at least a portion of the sheet expanding unit 16 that comes into contact with the sheet 8 in the sheet expanding step S20 has an inner peripheral portion greater in diameter than the outer peripheral portion of the workpiece 4 and an outer peripheral portion smaller in diameter than the outer peripheral portion of the sheet 8.

The sheet expanding unit 16 according to the present embodiment includes a main body 16a that is formed in a circular ring shape and a plurality of rollers 16b that are attached around the main body 16a. The plurality of rollers 16b are arrayed along the circumferential direction of the main body 16a and are configured to each roll about the main body 16a as the rotational axis.

The sheet holding unit 12, the workpiece holding unit 14, and the sheet expanding unit 16 are attached to the processing apparatus 10 in such a positional relation that the central axes of these units substantially match with each other, and also configured to move relative to one another by unillustrated moving units as needed.

The sheet holding unit 12 is, at normal times, located on the lower side (at a position separated from the holding surface 14a of the workpiece holding unit 14 to a side opposite the side where the workpiece holding unit 14 is present, in a direction of axis of the workpiece holding unit 14) of the workpiece holding unit 14 attached to the processing apparatus 10 with the holding surface 14a facing downward, but moves up and down relative to the workpiece holding unit 14 (moves along the direction of axis of the workpiece holding unit 14, in the vicinity of the height of the holding surface 14a) as needed.

In that instance, the sheet holding unit 12 may move relative to the workpiece holding unit 14, the workpiece holding unit 14 may move relative to the sheet holding unit 12, or both units may move. In a state in which the sheet holding unit 12 is located above the holding surface 14a, the sheet holding unit 12 is located in such a manner as to surround the periphery of the workpiece holding unit 14.

Similarly, the sheet expanding unit 16 is located on the lower side of the workpiece holding unit 14 at normal times, but moves up and down relative to the workpiece holding unit 14 as needed. Moreover, the sheet expanding unit 16 is, at normal times, located on the upper side of the position where the sheet 8 is held (between the height at which the sheet 8 is held in the sheet holding unit 12 (between the two sandwiching members 12a) and the height of the holding surface 14a of the workpiece holding unit 14) with respect to the sheet holding unit 12, but moves up and down relative to the sheet holding unit 12 and the workpiece holding unit 14 as needed.

In that instance, the sheet expanding unit 16 may move relative to the sheet holding unit 12 and the workpiece holding unit 14, the sheet holding unit 12 and the workpiece holding unit 14 may move relative to the sheet expanding unit 16, or all of the units may move relative to one another. In a state in which the sheet expanding unit 16 is located above the holding surface 14a, the sheet expanding unit 16 is located in such a manner as to surround the periphery of the workpiece holding unit 14.

The welding unit 18 is a unit for heating a portion (protruding portion 8a) of the sheet 8 in the procedures described later (welding step S60; see FIG. 4). In the example illustrated in FIGS. 2 and 3, the welding unit 18 is a heater that blows out heated air as warm air, and is attached, below the workpiece holding unit 14, to the processing apparatus 10, with the warm air vent facing the workpiece holding unit 14 on the upper side.

According to the present embodiment, a plurality of (four here) welding units 18 are arranged substantially symmetrically about the axis of the workpiece holding unit 14 in the circumferential direction. These welding units 18 are configured to rotate in the circumferential direction about the central axes of these units by an unillustrated rotation mechanism, relative to the sheet holding unit 12 and the workpiece holding unit 14.

Note that, for the welding unit 18, an apparatus having any mechanism or form that can suitably heat a portion (protruding portion 8a) of the sheet 8 may be adopted. The number of welding units 18 to be installed may be one or any appropriate number equal to or more than two. Further, the welding units 18 may not be arranged symmetrically about the axis of the workpiece holding unit 14.

In the processing apparatus 10, the cover member 20 illustrated in FIG. 2 is used. The cover member 20 is a member for protecting the workpiece 4 by covering the face side of the workpiece 4 in the procedures to be described later (protecting step S40 through welding step S60; see FIG. 4), and is supported by an unillustrated support unit at an appropriate position relative to the workpiece 4.

The cover member 20 according to the present embodiment includes a disk-shaped main surface portion 20a and a support member 20b provided on an edge of the main surface portion 20a.

The diameter of the outer peripheral portion of the main surface portion 20a is set to be greater than the diameter of the outer peripheral portion of the workpiece 4 but smaller than the diameter of the inner peripheral portion of the sheet holding unit 12.

The support member 20b is a ring-shaped portion that is protruding in the thickness direction of the disk-shaped main surface portion 20a (axial direction of the disk-shaped main surface portion 20a) from the outer peripheral portion of the disk-shaped main surface portion 20a. An outer peripheral surface 20c of the support member 20b has a tapered shape in which the more a position in the outer peripheral surface 20c along the axial direction separates from the main surface portion 20a, the smaller the diameter of the outer peripheral surface 20c is.

The angle formed by the outer peripheral surface 20c of the support member 20b relative to the central axis (virtual axis that penetrates the center of the disk-shaped main surface portion 20a perpendicularly to the surface formed by the main surface portion 20a) of the main surface portion 20a is, for example, approximately -3°, in the case of assuming that, for example, in a plane including the central axis of the main surface portion 20a, the point where the outer peripheral surface 20c crosses the main surface portion 20a is the center, the direction parallel to the central axis of the main surface portion 20a (the direction perpendicular to the surface formed by the main surface portion 20a) is 0°, the direction toward the outer side from the center along the radial direction of the main surface portion 20a is 90°, and the direction toward the inner side from the center along the radial direction of the main surface portion 20a is -90°.

Note that the shape of the cover member 20 is not limited to the example illustrated here and may variously be modified according to such conditions as the shape of the workpiece 4. For example, the main surface portion 20a may have a dome shape or a polygonal shape. The shape of the support member 20b may also be modified as appropriate according to the shape of the main surface portion 20a or the like.

In the procedures described later (welding step S60), a portion (protruding portion 8a) of the sheet 8 comes into contact with the outer peripheral surface 20c of the support member 20b, and the protruding portion 8a is heated in that state. In order to perform heating efficiently at that time, for example, the support member 20b including the outer peripheral surface 20c is preferably formed of a material having high thermal conductivity, such as metal.

Further, it would be convenient if the outer peripheral surface 20c is made of a material from which the material of the sheet 8 can easily peel off so that the protruding portion 8a of the sheet 8 in contact with

the outer peripheral surface 20c is easily peeled off. Alternatively, the protruding portion 8a may easily peel off by irregularities being formed in the outer peripheral surface 20c.

Note that, for the convenience of explanation, of the units and members described above, the workpiece unit 2 is not illustrated in FIG. 2. Moreover, the sheet expanding unit 16 and the cover member 20 are not illustrated in FIG. 3.

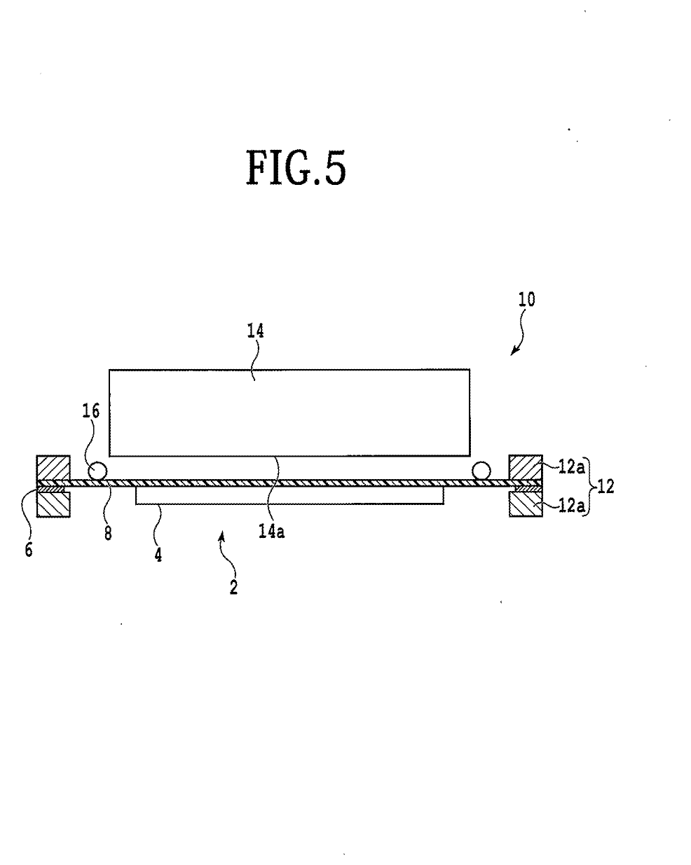

Next, procedures related to a chip manufacturing method and a chip distance increasing method using the processing apparatus 10 according to the present embodiment are described. FIG. 4 is a flowchart illustrating an example of procedures related to the chip manufacturing method and the chip distance increasing method. FIGS. 5 through FIG. 11 are each a cross-sectional side view schematically illustrating the state of each part in the steps of the procedures illustrated in FIG. 4.

The procedures illustrated in FIG. 4 include a sheet arranging step S10, the sheet expanding step S20, a workpiece holding step S30, the protecting step S40, the protruding portion forming step S50, and the welding step S60.

First, in a state in which the sheet 8 is held by the sheet holding unit 12, the sheet 8 and the sheet expanding unit 16 are arranged relative to each other in the state illustrated in FIG. 5 (sheet arranging step S10). FIG. 5 illustrates an example of layout of each part in the sheet arranging step S10.

In the example illustrated in FIG. 5, the sheet holding unit 12 includes the two sandwiching members 12a, and the two sandwiching members 12a sandwich the outer peripheral portion of the sheet 8 to which the frame 6 is fixed, so that the sheet 8 is held on the sheet holding unit 12.

Note that the sheet holding unit 12 may sandwich and hold the sheet 8 to which the frame 6 is not fixed, by the two sandwiching members 12a, for example. In that case, for example, in holding the sheet 8 on the sheet holding unit 12, the frame 6 is peeled off from the sheet 8 configuring the workpiece unit 2, and the sheet 8 is reaffixed to the sandwiching members 12a and held thereon.

Alternatively, the diameter of the outer peripheral portion of each of the sandwiching members 12a may be set to be smaller than the diameter of the inner peripheral portion of the frame 6. In that case, of the sheet 8 that is in a state in which the frame 6 is fixed to the outer peripheral portion thereof, an area of the sheet 8 that is on the inner side of the frame 6 and that is not fixed to the frame 6 is sandwiched and held by the two sandwiching members 12a.

Still alternatively, the sheet holding unit 12 may have one sandwiching member and be configured to hold the sheet 8 by sandwiching the sheet 8 between the one sandwiching member and the frame 6. In that case as well, for example, the frame 6 is peeled off from the sheet 8 configuring the workpiece unit 2, and the sheet 8 is reaffixed to the one sandwiching member and held thereon.

One surface of the sheet 8 held on the sheet holding unit 12 includes an adhesive layer to which the workpiece 4 is affixed and fixed. The sheet expanding unit 16 is arranged on a surface of the sheet 8 opposite the surface to which the workpiece 4 is affixed and comes into contact with the sheet 8.

In the state illustrated in FIG. 5, the sheet 8 is held on the sheet holding unit 12 in a state in which the workpiece 4 is facing downward, and the sheet expanding unit 16 is in contact with the sheet 8 from the upper side. In this state, the workpiece 4 is, in plan view, positioned on the inner side of the sheet expanding unit 16 forming a ring shape.

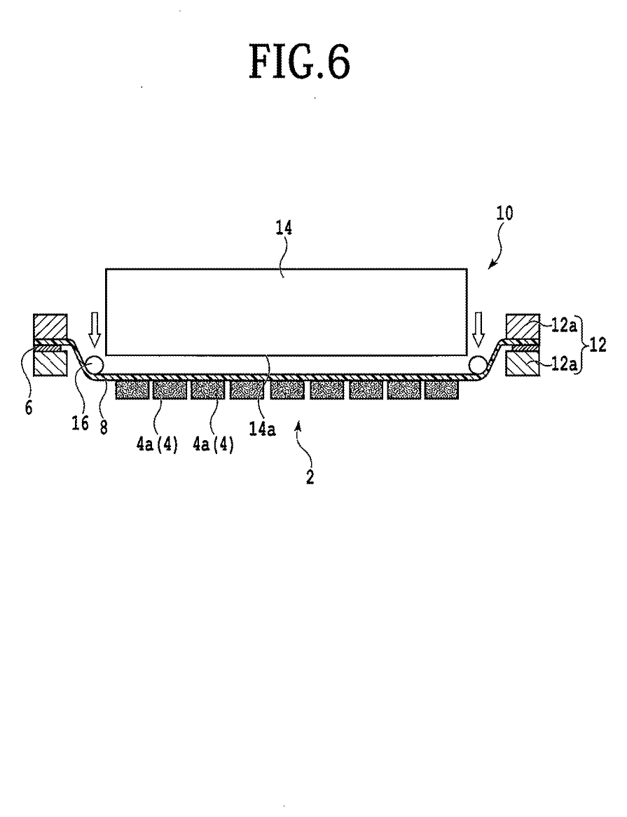

Next, as illustrated in FIG. 6, the sheet expanding unit 16 moves downward relative to the sheet holding unit 12 (sheet expanding step S20). FIG. 6 illustrates an example of layout of each part in the sheet expanding step S20.

In the state illustrated in FIG. 5, the sheet expanding unit 16 is in contact with the sheet 8 on the side opposite the side where the workpiece 4 is in contact with the sheet 8. From this state, in the sheet expanding step S20, the sheet expanding unit 16 moves downward toward the workpiece 4 side as illustrated in FIG. 6. With the sheet expanding unit 16 in contact with the sheet 8 moving relative to the sheet holding unit 12 holding the sheet 8 and the distance between the two units increasing as described above, the sheet 8 held on the sheet holding unit 12 is pressed by the sheet expanding unit 16 and expanded.

Note that, at this time, the sheet expanding unit 16 may move downward relative to the sheet holding unit 12, or the sheet holding unit 12 may move upward relative to the sheet expanding unit 16.

The workpiece 4, which is a wafer in which division initiating points are formed along the streets, is fixed to the sheet 8. In association with the expansion of the sheet 8, the workpiece 4, which is a wafer, is divided into a plurality of chips 4a along the streets while being fixed to the sheet 8 (note that, for the convenience of description, the chips 4a which have been formed by division of the workpiece 4 are hereinafter also treated as a form of the workpiece 4). When the sheet 8 is further expanded, the distance between the plurality of chips 4a fixed to the sheet 8 increases.

At this time, the rollers 16b of the sheet expanding unit 16 are in contact with the sheet 8. Each of the rollers 16b is configured to rotate about the annular main body 16a, and, when the sheet 8 is expanded, rotates in a direction substantially along the expansion direction of the sheet 8 that expands along the radial direction. As a result, the sheet 8 is allowed to move relative to the sheet expanding unit 16 by rotation of the rollers 16b and smoothly be expanded, while being in contact with the sheet expanding unit 16.

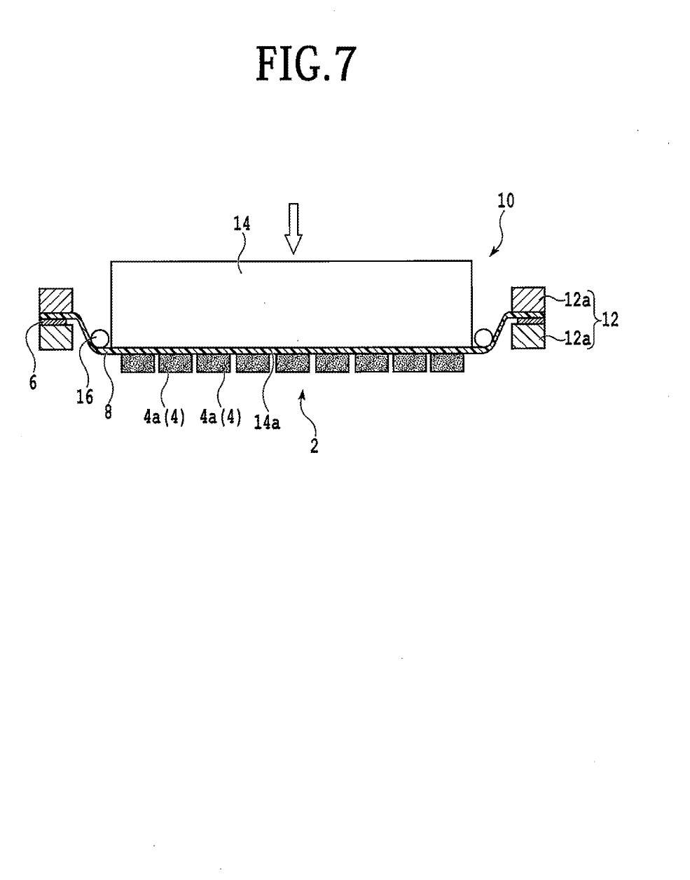

After the workpiece (wafer) 4 has been divided and the distance between the chips 4a has been increased by the expansion of the sheet 8, the workpiece 4 is held on the workpiece holding unit 14 as illustrated in FIG. 7 (workpiece holding step S30). FIG. 7 illustrates an example of layout of each part in the workpiece holding step S30.

In the workpiece holding step S30, the surface of the sheet 8 opposite the surface to which the workpiece 4 is fixed is held on the holding surface 14a of the workpiece holding unit 14. The holding surface 14a of the workpiece holding unit 14 is configured to hold the object that comes into contact with the holding surface 14a, by a negative pressure, as described above. The workpiece holding unit 14 comes into contact with an area of the sheet 8 to which the workpiece 4 is fixed at the holding surface 14a and supplies a negative pressure to the sheet 8, to thereby hold the workpiece 4 on the holding surface 14a with the sheet 8 sandwiched therebetween.

When the workpiece 4 is to be held on the workpiece holding unit 14 by suction force in the manner described above, the workpiece holding step S30 is preferably performed after the sheet expanding step S20 but before the protruding portion forming step S50.

If the workpiece 4 is held under suction on the holding surface 14a of the workpiece holding unit 14 before the sheet expanding step S20, the suction force may hinder the expansion of the sheet 8. Moreover, at the time when the protruding portion forming step S50 is to be performed, the workpiece 4 is preferably held on the workpiece holding unit 14 and bound thereon so that the protruding portion 8a is suitably formed.

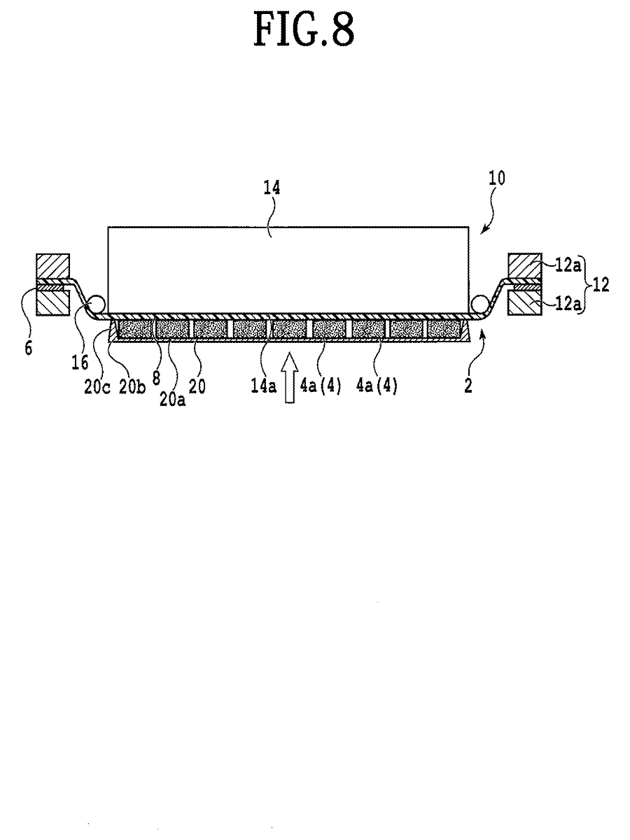

Next, as illustrated in FIG. 8, the cover member 20 is disposed on the workpiece 4 (chips 4a) (protecting step S40). FIG. 8 illustrates an example of layout of each part in the protecting step S40.

The workpiece 4 is fixed to one surface of the sheet 8, and the holding surface 14a of the workpiece holding unit 14 is in contact with the other surface of the sheet 8 opposite the one surface and is holding the workpiece 4. Relative to this workpiece 4, the main surface portion 20a is positioned on the lower side (the side opposite the side where the holding surface 14a of the workpiece holding unit 14 holding the workpiece 4 is present), and the workpiece 4 is covered with the cover member 20 in such a manner that the support member 20b surrounds the outer periphery of the workpiece 4. Note that, in the example illustrated in FIG. 8, one surface (upper surface side) of the main surface portion 20a is in contact with the workpiece 4, but depending on the thickness of the workpiece 4, the size of the support member 20b, and the like, the workpiece 4 may be covered with the cover member 20 in a state in which the main surface portion 20a is separated from the workpiece 4.

In this state, a distal end of the support member 20b extending upward from the outer periphery of the main surface portion 20a is in contact with a portion of the sheet 8 that is located around the workpiece 4. That is, the sheet 8 is, at this portion, sandwiched between the support member 20b of the cover member 20 and the holding surface 14a of the workpiece holding unit 14.

Note that the workpiece holding step S30 and the protecting step S40 may be performed in any order. It is sufficient if the protecting step S40 is performed before the protruding portion forming step S50 or the welding step S60, and the protecting step S40 may be performed before the workpiece holding step S30.

Moreover, for example, there may be assumed a case where the workpiece holding unit 14 itself does not include a mechanism for holding under suction an object and holds the object by sandwiching the object between the workpiece holding unit 14 and the cover member 20. In that case, the workpiece holding step S30 that holds the workpiece 4 as an object and the protecting step S40 that disposes the cover member 20 on the workpiece 4 are performed as the same step.

When the workpiece 4 is divided into the chips 4a and the workpiece 4 (chips 4a) is held between the holding surface 14a of the workpiece holding unit 14 and the main surface portion 20a of the cover member 20, the sheet holding unit 12 moves downward relative to the workpiece holding unit 14, the sheet expanding unit 16, and the cover member 20, and approaches the sheet expanding unit 16.

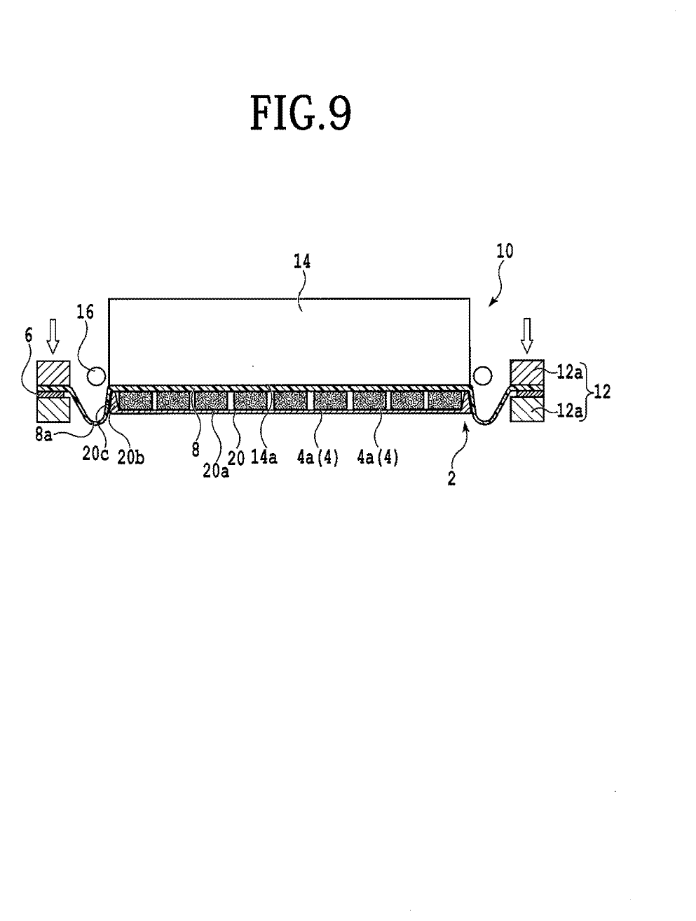

As a result, a portion (protruding portion 8a) protruding relative to a surface formed by other portions is formed in a part of the sheet 8 (protruding portion forming step S50). FIG. 9 illustrates an example of layout of each part in the protruding portion forming step S50.

In the previous sheet expanding step S20, as a result of the distance between the sheet expanding unit 16 in contact with the sheet 8 and the sheet holding unit 12 holding the sheet 8 being increased, the sheet 8 positioned on the inner side of the sheet holding unit 12 is expanded, and the total area of the sheet 8 on the inner side of the sheet holding unit 12 becomes greater than the area of a virtual surface on the inner side of the inner periphery of the sheet holding unit 12. Moreover, in the workpiece holding step S30 and the protecting step S40, the workpiece 4 is held on the holding surface 14a of the workpiece holding unit 14, and the portion of the sheet 8 located around the workpiece 4 is sandwiched by the holding surface 14a and the support member 20b of the cover member 20.

When the sheet holding unit 12 and the sheet expanding unit 16 approach each other in this state, a portion of the sheet 8 between the two units slackens, and this slackened portion becomes the protruding portion 8a. In the example illustrated in FIG. 9, the slackened portion of the sheet 8 droops downward by its own weight, so that the protruding portion 8a that has a U-shaped cross section protruding downward is formed over the circumferential direction in such a manner to surround the outer side of the area where the workpiece 4 is located.

Note that, at this time, instead of the sheet holding unit 12 moving, for example, the workpiece holding unit 14, the sheet expanding unit 16, and the cover member 20 may move upward.

Moreover, for example, the protruding portion 8a may be formed by the workpiece holding unit 14, together with the cover member 20, moving upward relative to the sheet holding unit 12 (in a direction in which the workpiece 4 held between the workpiece holding unit 14 and the cover member 20 approaches the sheet holding unit 12) while the sheet expanding unit 16 is in contact with the sheet 8. In this case, the protruding portion 8a is formed without the sheet 8 slackened but with tension being kept.

Note that, at that time, in association with the rise of the workpiece holding unit 14 and the cover member 20 relative to the sheet holding unit 12, the sheet expanding unit 16 may gently rise relative to the sheet holding unit 12. If the speed of rising of the sheet expanding unit 16 relative to the sheet holding unit 12 is approximately 1/2 of the speed of rising of the workpiece holding unit 14 and the cover member 20 relative to the sheet holding unit 12, the protruding portion 8a would be formed without the sheet 8 being overly expanded but with the tension of the sheet 8 being kept.

Incidentally, in the procedures illustrated in FIG. 4, the workpiece holding step S30 and the protecting step S40 are performed before the protruding portion forming step S50, and the protruding portion forming step S50 is performed in a state in which the sheet 8 is sandwiched between the holding surface 14a of the workpiece holding unit 14 and the support member 20b of the cover member 20.

When the protruding portion forming step S50 is performed in this state, the portion of the sheet 8 sandwiched between the holding surface 14a and the support member 20b is bound at that position, so that, even if such units as the sheet holding unit 12, the sheet expanding unit 16, the workpiece holding unit 14, and the cover member 20 move relative to one another, the area of the sheet 8 on the inner side of the support member 20b is unlikely to move. This offers such an advantage that the distance between the plurality of chips 4a fixed to that area can easily be maintained.

Further, in the protruding portion forming step S50, the workpiece holding unit 14 and the cover member 20 may be moved further downward relative to the sheet holding unit 12, from a state in which the sheet 8 is sandwiched between the holding surface 14a and the support member 20b as illustrated in FIG. 8.

In a case where such an operation is performed, a distance between an area (outer edge portion) held by the sheet holding unit 12 and an area (central portion) held by the holding surface 14a of the workpiece holding unit 14 in the sheet 8 further increases, and an area (area around an area sandwiched between the holding surface 14a of the workpiece holding unit 14 and the cover member 20 in the sheet 8; this area is called a “middle area” for the sake of convenience) between the abovementioned two areas in the sheet 8 further expands.

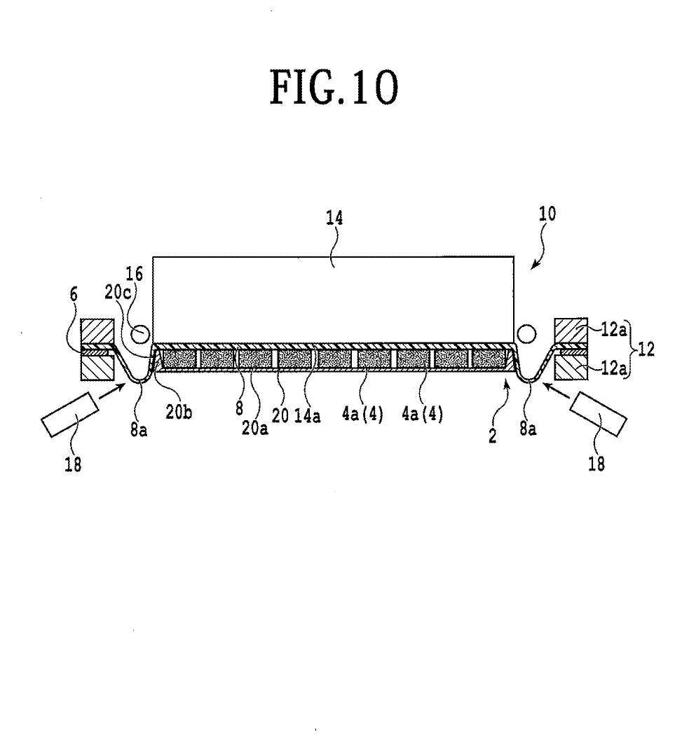

As a result, the size of the slack (protruding portion 8a; see FIGS. 9 and 10) formed in the protruding portion forming step S50 is increased, making it easier to weld the protruding portion 8a in the subsequent welding step S60.

In expanding the middle area of the sheet 8, sandwiching and holding the sheet 8 between the workpiece holding unit 14 and the support member 20b by pressing the workpiece holding unit 14 and the cover member 20 against each other allows the middle area to more easily expand. Further, turning on the supply of the negative pressure in the workpiece holding unit 14 and thereby holding the sheet 8 under suction on the holding surface 14a similarly makes it easier for the middle area of the sheet 8 to expand. Moreover, sandwiching the sheet 8 by the holding surface 14a and the support member 20 and holding the sheet 8 under suction on the holding surface 14a may both be executed.

Alternatively, for example, also possible is a step of expanding the middle area of the sheet 8 by lowering the sheet expanding unit 16 relative to the workpiece holding unit 14 and the sheet holding unit 12 in a state in which the sheet 8 is sandwiched between the holding surface 14a and the support member 20b or held under suction on the holding surface 14a by the negative pressure.

In expanding the middle area, when the middle area is heated to have a higher temperature, the material of the sheet 8 softens, making it easier for the middle area to expand. The middle area can be heated by warm air being sent out from the welding unit 18 (see FIG. 10), for example. Alternatively, the middle area may be heated by a mechanism (not illustrated) provided separately from the welding unit 18.

Note that the protruding portion can be formed in various manners other than the abovementioned manner. For example, while illustration is omitted, it is also possible to form a protruding portion that has an upwardly protruding shape by supporting the sheet 8 by another support member or the like such that the sheet 8 does not droop downward. Alternatively, in theory, a protruding portion having an upwardly protruding shape may be formed by sending an air current upwardly to the sheet 8 from the welding unit 18.

Moreover, a case where the procedures ranging from the sheet arranging step S10 to the protruding portion forming step S50 are performed in a state in which the workpiece 4 is held on the lower side of the sheet 8 has been explained here, but the abovementioned procedures may be performed in a state in which the workpiece 4 is held on the upper side of the sheet 8, for example. In that case, for example, the sheet expanding unit 16 and the workpiece holding unit 14 are positioned on the lower side opposite the side where the workpiece 4 is present relative to the sheet 8, and the cover member 20 is positioned on the upper side similarly to the workpiece 4 relative to the sheet 8.

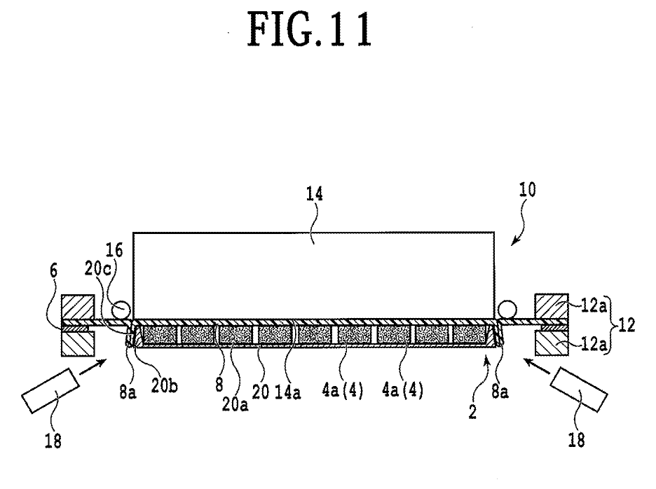

Next, the welding step S60 is described. After the protruding portion 8a has been formed in a part of the sheet 8 by the procedures described above, the protruding portion 8a is heated by the welding unit 18, and portions of the sheet 8 forming the protruding portion 8a are welded (welding step S60). FIGS. 10 and 11 each illustrate an example of a state of each part in the welding step S60.

As illustrated in FIG. 9, the protruding portion 8a, which is a portion of the sheet 8, is formed to have a U-shaped cross section, and has surfaces forming the inner side of the U-shape and facing each other. In this state, the protruding portion 8a slackens and droops downward, and one of the surfaces forming the outer side of the U-shape comes into contact with the outer peripheral surface 20c of the support member 20b provided as part of the cover member 20.

In the welding step S60, as illustrated in FIG. 10, one of the surfaces forming the outer side of the protruding portion 8a forming the U-shaped cross section (the surface opposite the surface in contact with the outer peripheral surface 20c of the support member 20b) is heated by warm air blown out from the welding unit 18 on the lower side. During that time, the other one of the surfaces forming the outer side of the protruding portion 8a (the surface in contact with the outer peripheral surface 20c of the support member 20b) is supported by the outer peripheral surface 20c of the support member 20b.

In this manner, the protruding portion 8a forming a U-shaped cross section is heated while being pressed against the outer peripheral surface 20c of the support member 20b by the pressure of warm air, as illustrated in FIG. 11. That is, in a state in which the protruding portion 8a is extending along the outer peripheral surface 20c of the support member 20b, warm air that flows toward the protruding portion 8a is supplied from the side opposite the side where the support member 20b is present across the protruding portion 8a.

In this state, portions of the sheet 8 are in contact with each other while facing each other at the protruding portion 8a. A plurality of portions (for example, among the portions of the sheet 8 forming a U-shaped cross section in the protruding portion 8a in FIG. 11, one portion on the left side, and another portion on the right side) of the sheet 8 forming the protruding portion 8a are welded by the heat supplied from the warm air. Heating is performed in a state in which the portions of the sheet 8 forming the protruding portion 8a are in close contact with each other, allowing more secure welding.

Moreover, if the material forming the outer peripheral surface 20c of the support member 20b is metal or the like that is a material with high thermal conductivity, the heat supplied from warm air is quickly transmitted through the support member 20b, so that the protruding portion 8a is welded efficiently.

Further, at the time of welding, if the warm air is supplied at an angle that crosses the outer peripheral surface 20c of the support member 20b as illustrated in FIGS. 10 and 11, force generated by the warm air supplied in this direction presses the protruding portion 8a against the outer peripheral surface 20c and allows the protruding portion 8a to be welded more efficiently.

At the time of welding, if the welding unit 18 rotates relative to the sheet holding unit 12, the position to which warm air is supplied from the welding unit 18 moves along the circumferential direction. As a result, the protruding portion 8a formed on the outer side of the portion of the sheet 8 that is holding the workpiece 4 is welded over the entire circumference. Note that, in the relative rotation of the welding unit 18 and the sheet holding unit 12, the welding unit 18 side may rotate, the sheet holding unit 12 side (the sheet holding unit 12, the workpiece holding unit 14, and the cover member 20) may rotate, or both units may rotate.

The welding step S60 is performed in a state in which the cover member 20 is arranged between the heat source (welding unit 18) used for welding and the workpiece 4 (chips 4a). This protects the workpiece 4 from the heat of warm air and contaminants such as debris of the sheet 8 that may be included in the warm air.

After the protruding portion 8a of the sheet 8 has been welded in the manner described above, the cover member 20 is removed from the position of covering the workpiece 4. At this time, the protruding portion 8a is peeled off from the outer peripheral surface 20c of the support member 20b. Here, forming the outer peripheral surface 20c of the support member 20b by a material from which the material of the sheet 8 can easily peel off makes it easier to separate the protruding portion 8a from the support member 20b.

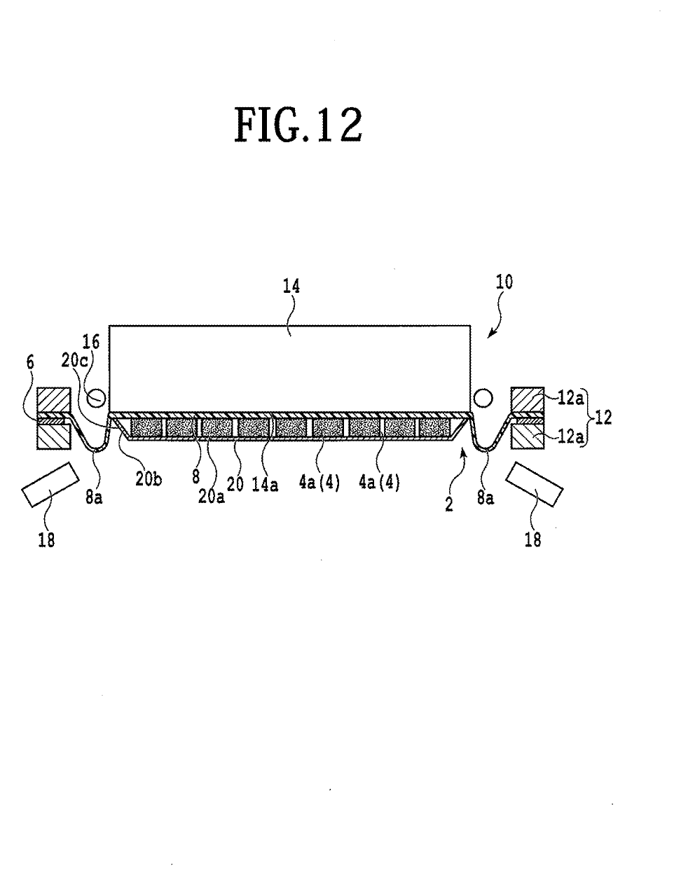

The angle formed by the support member 20b is next described. FIG. 12 is a cross-sectional side view schematically illustrating another example of a state of each part in the welding step S60.

As described above, in the examples illustrated in FIGS. 2, 3, and 5 through 11, the outer peripheral surface 20c of the support member 20b has a tapered shape in which the more a position in the outer peripheral surface 20c along the axial direction separates from the main surface portion 20a, the smaller the diameter of the outer peripheral surface 20c is. The angle formed by the outer peripheral surface 20c of the support member 20b relative to the central axis of the main surface portion 20a (this angle is hereinafter referred to as an “angle formed by the outer peripheral surface 20c of the support member 20b” or simply as an “angle of the outer peripheral surface 20c”) is approximately -3 °, in the case of assuming that, for example, in the plane including the central axis of the disk-shaped main surface portion 20a, the point where the outer peripheral surface 20c crosses the main surface portion 20a is the center, the direction upward (toward the sheet 8 side) along the direction parallel to the central axis of the main surface portion 20a is 0°, the direction toward the outer side along the radial direction of the main surface portion 20a from the center is 90°, and the direction toward the inner side along the radial direction of the main surface portion 20a from the center is -90°.

In contrast, in the example illustrated in FIG. 12, the outer peripheral surface 20c of the support member 20b has a tapered shape in which the more a position in the outer peripheral surface 20c along the axial direction separates from the main surface portion 20a, the greater the diameter of the outer peripheral surface 20c is. The angle formed by the outer peripheral surface 20c of the support member 20b is set to be approximately 40°.

The inventors of the present application conducted an experiment for verifying the easiness of welding for each of the cover member 20 shaped as illustrated in FIGS. 10 and 11 and the cover member 20 shaped as illustrated in FIG. 12. As the welding unit 18, a heater of a system blowing out warm air upwardly was used as illustrated in FIGS. 10 through 12.

In the experiment, welding was conducted with the rotation speed of the welding unit 18 relative to the sheet holding unit 12 being variously changed, and the states of the protruding portion 8a after the welding work at each rotation speed were compared and verified. For the rotation speed of the welding unit 18, five conditions of 1°/sec, 2°/sec, 3°/sec, 4°/sec, and 5°/sec were set.

As a result, when the cover member 20 in the form illustrated in FIGS. 10 and 11 (the cover member 20 in which the angle formed by the outer peripheral surface 20c of the support member 20b is approximately -3°) was used, the protruding portion 8a was substantially favorably welded at any of the rotation speeds of the welding unit 18. Particularly, when the rotation speed was 1°/sec through 3°/ sec, the entire circumference of the protruding portion 8a was thoroughly welded. When the rotation speed was 4°/sec and 5°/sec, welding failure was found in some portions of the protruding portion 8a, but the slack of the sheet 8 was eliminated to a certain degree.

In contrast, when the cover member 20 in the form illustrated in FIG. 12 (the cover member 20 in which the angle formed by the outer peripheral surface 20c of the support member 20b is approximately 40°) was used, welding failure was found over substantially the entire circumference of the protruding portion 8a in the case where the rotation speed of the welding unit 18 was 3°/sec through 5°/sec. In the case where the rotation speed was 2°/sec, while welding failure was found in some portions of the protruding portion 8a, the slack of the sheet 8 was eliminated to a certain degree. In the case where the rotation speed was 1°/sec, the entire circumference of the protruding portion 8a was thoroughly welded.

As described above, no matter which of the cover member 20 illustrated in FIGS. 10 and 11 in which the angle of the outer peripheral surface 20c is small or the cover member 20 illustrated in FIG. 12 in which the angle of the outer peripheral surface 20c is large is used, if the rotation speed of the welding unit 18 is sufficiently low, a greater amount of heating per length and per unit time in the circumferential direction of the protruding portion 8a can lead to favorable welding of the protruding portion 8a. Yet, a lower rotation speed of the welding unit 18 would require more time for welding, adversely affecting the production efficiency.

That is, in terms of welding efficiency, a smaller angle of the outer peripheral surface 20c within the range of -90° to 90° can be said to be advantageous. This may be due to the fact that, in the case where a portion of the sheet 8 droops down and serves as the protruding portion 8a, the smaller the angle of the outer peripheral surface 20c is, the easier the protruding portion 8a comes into contact with the outer peripheral surface 20c, and hence, the easier the protruding portion 8a is pressed against the outer peripheral surface 20c by warm air.

Meanwhile, in terms of a smaller size of each part configuring the processing apparatus 10, a larger angle of the outer peripheral surface 20c is more advantageous. In the procedures described above, since the support member 20b needs to surround the workpiece 4, the diameter of a distal end portion of the support member 20b must not be smaller than the diameter of the workpiece 4. Accordingly, the smaller the angle of the outer peripheral surface 20c is, the larger the diameter of the distal end portion of the support member 20b (that is, the diameter of the outer peripheral portion of the main surface portion 20a of the cover member 20) becomes, and further, other units would be set to be larger according to the size of the cover member 20, as needed.

As described above, insofar as a favorable welding is performed, the angle of the outer peripheral surface 20c is preferably as small as possible within the range of -90° to 90°. As illustrated in FIGS. 10 and 11, in the case where the method of pressing the protruding portion 8a against the support member 20b and heating the protruding portion 8a by warm air is adopted, the angle formed by the outer peripheral surface 20c of the support member 20b is, for example, preferably equal to or greater than -15° but equal to or smaller than -2°, and more preferably equal to or greater than -5° but equal to or smaller than -2°.

Note that, here, a case where a heater that blows out warm air upwardly is included as the welding unit 18 used in the welding step S60 in the processing apparatus 10 has been described, but the mechanism, form, and the like of the welding unit are not limited to the examples described here. As the welding unit, apparatuses of various mechanisms and forms that can favorably perform welding of the protruding portion 8a may be adopted.

For example, the welding unit may be an apparatus that comes into contact with the protruding portion 8a and heats the protruding portion 8a or an apparatus that applies light beams such as infrared rays to the protruding portion 8a to heat the protruding portion 8a.

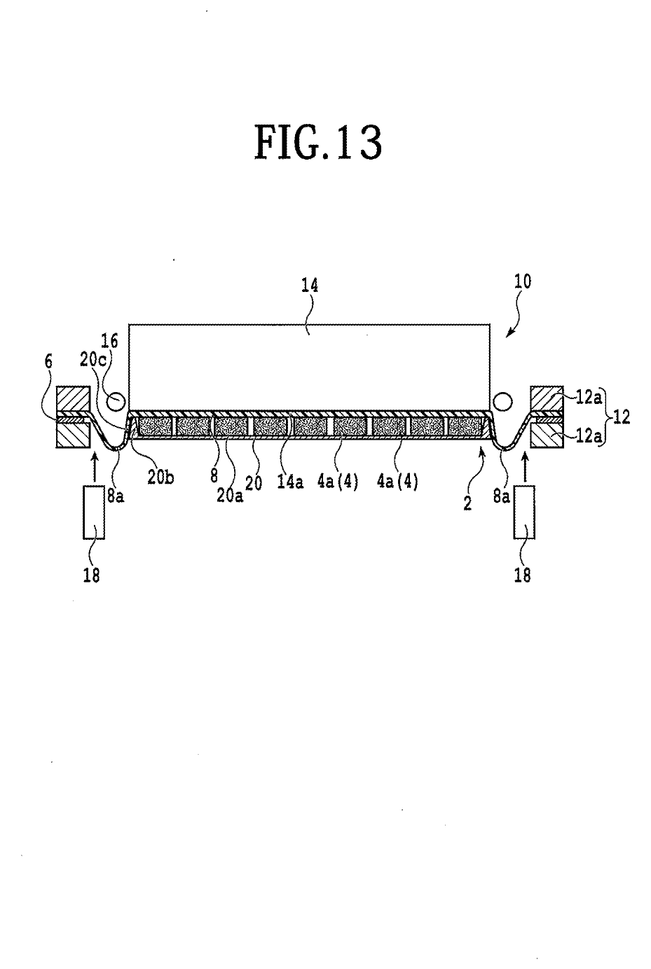

FIGS. 13 through 15 are each a diagram illustrating a modification of the welding unit and a cross-sectional side view schematically illustrating a further example different from the above regarding the state of each part in the welding step S60.

In the example illustrated in FIG. 13, a welding unit 18 of a warm air system similar to the welding unit 18 described in FIGS. 2, 3, 10, and 11 is used, but each welding unit 18 has a different angle and is configured to blow out warm air in a substantially vertical direction.

In the examples illustrated in FIGS. 2, 3, 10, and 11, the welding unit 18 supplies warm air at an oblique angle (at an angle of blowing warm air toward the inner side with respect to the radial direction) to effectively press the protruding portion 8a against the outer peripheral surface 20c of the support member 20b by warm air. Yet, if a sufficient amount of warm air is supplied, as in the example illustrated in FIG. 13, for example, even if warm air is blown out at a substantially vertical angle, the protruding portion 8a would sufficiently be pressed against the outer peripheral surface 20c of the support member 20b, and welding would be performed favorably.

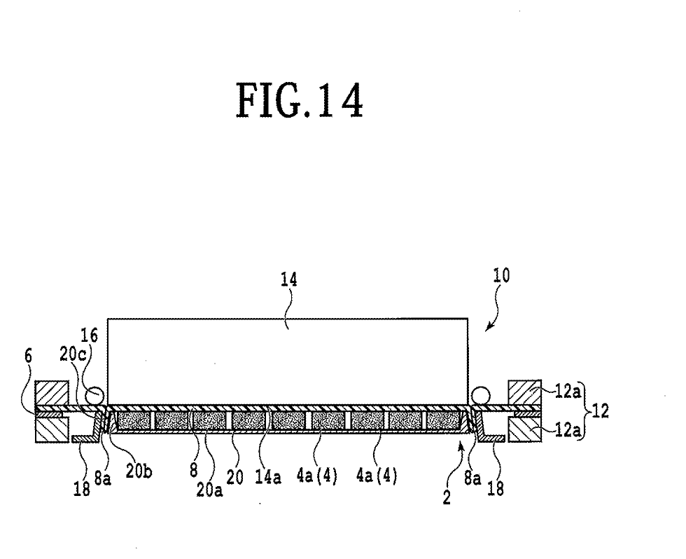

In the example illustrated in FIG. 14, a heater of a system of coming into contact with the protruding portion 8a and heating the protruding portion 8a is included as the welding unit 18. The welding unit 18 in the example illustrated in FIG. 14 is an electric heater, for example, and is configured to heat the protruding portion 8a while pressing the protruding portion 8a against the outer peripheral surface 20c of the support member 20b.

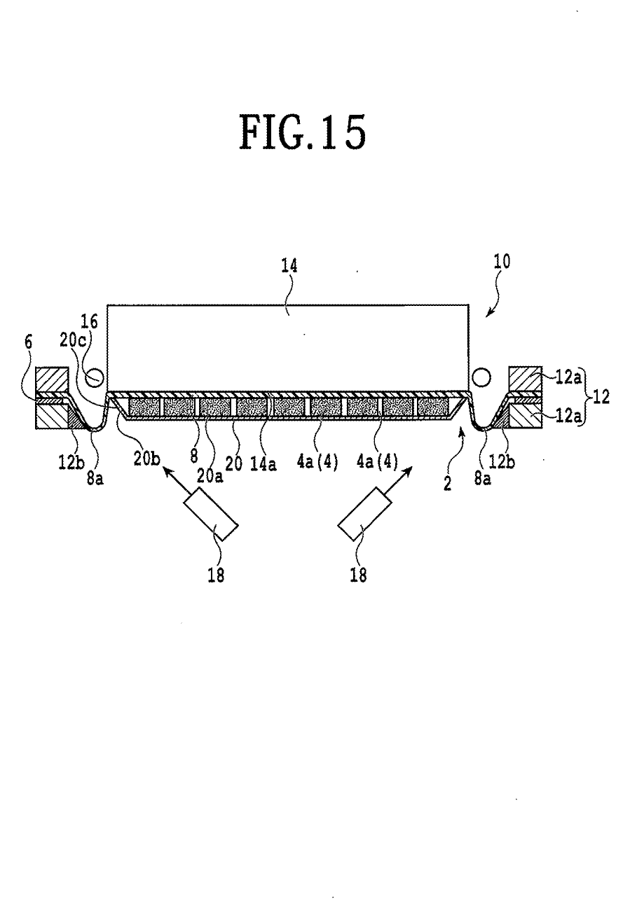

In the example illustrated in FIG. 15, a support member 12b for supporting the protruding portion 8a of the sheet 8 is provided at a position different from that of the cover member 20 (sheet holding unit 12). The support member 12b is provided on the inner peripheral surface of one of the two sandwiching members 12a that are included in the sheet holding unit 12 (one on the side where the protruding portion 8a of the sheet 8 held on the sheet holding unit 12 is formed; the lower side in FIG. 15), and forms a cone-shaped slanted surface in which the diameter decreases as the distance from the portion holding the sheet 8 increases in the axial direction.

After the sheet 8 has been expanded, the protruding portion 8a drooping downward comes into contact with this slanted surface of the support member 12b. In the examples illustrated in FIGS. 9 through 11, a portion of the protruding portion 8a on the inner side in the radial direction comes into contact with the support member 20b provided in the cover member 20, but in the example illustrated in FIG. 15, the portion of the protruding portion 8a on the outer side in the radial direction comes into contact with the support member 12b provided on the sheet holding unit 12.

In association with this, the welding unit 18 is provided to blow out warm air toward the outer side in the radial direction to the protruding portion 8a from the position on the inner side in the radial direction. At the time of welding, warm air is blown toward the outer side from the inner side in the radial direction to the protruding portion 8a, and the protruding portion 8a is heated while being pressed against the support member 12b located on the outer side in the radial direction.

In a case where the support member 12b is provided in such a manner, the angle formed by the slanted surface of the support member 12b is, for example, preferably approximately equal to or greater than 15° but equal to or smaller than 2°, more preferably approximately equal to or greater than 5° but equal to or smaller than 2°, and typically approximately 3°, in the case of assuming that the direction upward (toward the sheet 8 side) along the axial direction of the support member 12b forming a ring shape is 0°, the direction toward the outer side along the radial direction from the center of the support member 12b is 90°, and the direction toward the inner side along the radial direction from the center of the support member 12b is -90°.

In the example illustrated in FIG. 15, the support member 12b is positioned on the outer side in the radial direction relative to the protruding portion 8a formed in an area of the sheet 8 surrounding the workpiece 4, and welding is performed in such a manner that the protruding portion 8a is pressed against the support member 12b.

When the protruding portion 8a is welded in such a manner, the protruding portion 8a obtained after welding is positioned on the outer side in the radial direction, that is, an area that is farther from the workpiece 4 fixed on the inner side of the protruding portion 8a in the radial direction. When the protruding portion 8a is formed at such a position, in a case where some kind of operation such as picking up of the chips 4a is to be performed on the workpiece 4 after welding, there is an advantage that the protruding portion 8a is less likely to hinder such operation.

Besides, as the welding unit and the support member, an apparatus of various mechanisms and forms can be assumed, while various kinds of forms can also be assumed for the welding step using the welding unit and the support member.

For example, in the case of using a welding unit of a warm air system, welding can be performed without the support member being provided and by the protruding portion being supported through adjustment of the direction and amount of warm air. In that case, warm air is supplied from both sides of the protruding portion to the protruding portion drooping downward and forming a U-

shaped cross section, for example, so that the surfaces on the inner side of the protruding portion come into contact with each other in a state in which the protruding portion is sandwiched from both sides by the warm air, and welding is performed by the heat of the warm air.

Alternatively, also possible is a method of performing welding by causing a contact-type welding unit to come into contact with the protruding portion in a manner of sandwiching the protruding portion from both sides. In this case as well, welding can be performed without the use of a support member.

Further, the welding step may be performed in a state in which the workpiece 4 is held on the upper side of the sheet 8. In that case, for example, the sheet expanding unit 16 and the workpiece holding unit 14 are positioned on the lower side that is opposite the side where the workpiece 4 is held with respect to the sheet 8, and the cover member 20 is positioned on the upper side similarly to the workpiece 4 with respect to the sheet 8.

In this state, with wind being blown upwardly to the sheet 8 from a blower unit provided below the sheet holding unit 12, for example, a protruding portion 8a having an upwardly protruding shape is formed in the sheet 8. Alternatively, with the sheet 8 being supported so as not to droop downward by a support unit provided below the sheet holding unit 12, an upwardly protruding-shaped protruding portion 8a is formed in the sheet 8.

Welding is performed on the upwardly protruding-shaped protruding portion 8a formed in the manner described above by warm air being blown from the welding unit 18 provided above the sheet holding unit 12. Alternatively, welding is performed by a contact-type welding unit 18 coming into contact with the protruding portion 8a.

As described above, in the processing apparatus 10 according to the present embodiment and the chip manufacturing method and chip distance increasing method using the processing apparatus 10 according to the present embodiment, the workpiece 4 is divided through expansion of the sheet 8, to manufacture the chips 4a, and the distance between the chips 4a is increased, so that the protruding portion 8a formed in a part of the sheet 8 is welded.

After the sheet 8 has been expanded, if no particular treatment is performed on the slack of the expanded sheet 8, the chips 4a may move and come into contact with each other. However, according to the procedures described above, the protruding portion 8a formed by expansion of the sheet 8 is welded by heat, so that the slack that could be generated in the sheet 8 is suppressed, restraining the chips 4a from coming into contact with each other or the distance between the chips 4a from decreasing.

Here, the surface of the sheet 8 that holds the workpiece 4 is provided with an adhesive layer for affixing the workpiece 4 or the frame 6 as described above. If the protruding portion 8a is formed such that portions of the adhesive layer face each other, the portions forming the protruding portion 8a may be bonded to each other by sandwiching the protruding portion 8a from the outer side.

However, according to the example described above, the materials of the sheet 8 are welded by heating, so that, regardless of the presence or absence of an adhesive layer or the position thereof, the portions forming the protruding portion 8a can be bonded to each other. Accordingly, as illustrated in FIGS. 9 through 11, for example, even if the workpiece 4 is supported on the lower side of the sheet 8 (accordingly, the adhesive layer is positioned on the lower surface side of the sheet 8) and the protruding portion 8a is formed to protrude downwardly (that is, the adhesive layer is located on the outer side of the protruding portion 8a forming a U-shaped cross section but not formed on the inner side where portions of the adhesive layer face each other), portions of the sheet 8 that form the protruding portion 8a can favorably be bonded to each other.

Besides, structural and methodical details according to the above embodiment and modifications thereof may be changed or modified without departing from the scope of the present invention.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A chip manufacturing method that divides a workpiece to manufacture chips, the manufacturing method comprising:
dividing the workpiece into a plurality of chips by expanding a sheet to which the workpiece in which division initiating points are formed is fixed;
after the workpiece has been divided into a plurality of chips, forming, in a part of the sheet that has been expanded, a protruding portion protruding relative to a surface formed by other portions; and
welding a plurality of portions of the sheet that form the protruding portion and are in contact with each other, by heating the protruding portion.

2. The chip manufacturing method according to claim 1, wherein, when the sheet is to be welded, while the protruding portion is heated from one of surfaces forming an outer side of the protruding portion, another one of the surfaces forming the outer side of the protruding portion is supported by a support member.

3. The chip manufacturing method according to claim 2, wherein
the sheet is welded in a state in which a cover member is arranged between a heat source used for welding and the workpiece, and
the cover member includes the support member that supports the protruding portion.

4. The chip manufacturing method according to claim 3, further comprising:
after the workpiece is divided but before the protruding portion is formed, holding a surface of the sheet opposite a surface to which the workpiece is fixed, by a holding surface of the workpiece holding unit including a member having the holding surface for holding the workpiece, wherein
the cover member is disposed on the workpiece before the protruding portion is formed, and
the protruding portion is formed in a state in which the sheet is sandwiched between the holding surface of the workpiece holding unit and the cover member.

5. The chip manufacturing method according to claim 4, wherein, when the protruding portion is to be formed, an area around an area sandwiched between the holding surface of the workpiece holding unit and the cover member in the sheet is further expanded, in a state in which a part of the sheet is sandwiched between the holding surface of the workpiece holding unit and the cover member.

6. The chip manufacturing method according to claim 2, wherein, when the sheet is to be welded, the protruding portion is heated by supply of warm air that flows toward the protruding portion from a side opposite the side where the support member is present across the protruding portion.

7. The chip manufacturing method according to claim 1, wherein, when the protruding portion is to be formed, the protruding portion is formed by the slackened sheet drooping downward.

8. The chip manufacturing method according to claim 2, wherein, when the protruding portion is to be formed, the protruding portion is formed by the slackened sheet drooping downward.

9. The chip manufacturing method according to claim 3, wherein, when the protruding portion is to be formed, the protruding portion is formed by the slackened sheet drooping downward.

10. The chip manufacturing method according to claim 4, wherein, when the protruding portion is to be formed, the protruding portion is formed by the slackened sheet drooping downward.

11. The chip manufacturing method according to claim 5, wherein, when the protruding portion is to be formed, the protruding portion is formed by the slackened sheet drooping downward.

12. The chip manufacturing method according to claim 6, wherein, when the protruding portion is to be formed, the protruding portion is formed by the slackened sheet drooping downward.

13. A chip distance increasing method of increasing a distance between a plurality of chips fixed to a sheet, the method comprising:
increasing the distance between the plurality of chips by expanding the sheet to which the plurality of chips are fixed;
after a workpiece has been divided into a plurality of chips, forming, in a part of the expanded sheet, a protruding portion protruding relative to a surface formed by other portions; and
welding portions of the sheet that form the protruding portion, by heating the protruding portion.

14. A processing apparatus that processes a sheet to which a workpiece is fixed, the apparatus comprising:
a sheet holding unit that holds the sheet to which the workpiece is fixed;
a sheet expanding unit that expands the sheet held on the sheet holding unit; and
a welding unit that heats a protruding portion formed in a part of the sheet expanded by the sheet expanding unit, as a portion protruding relative to other portions, and welds a plurality of portions of the sheet that form the protruding portion and are in contact with each other.
